(19) United States
(12) Patent Application Publication
(10) Pub. No.: US 2020/0258452 A1
(43) Pub. Date: Aug. 13, 2020

(54) PIXEL CIRCUIT AND METHOD OF DRIVING THE SAME, DISPLAY PANEL AND METHOD OF FORMING THE SAME AND DISPLAY DEVICE

(71) Applicant: BOE TECHNOLOGY GROUP CO., LTD., Beijing (CN)

(72) Inventors: Yu Feng, Beijing (CN); Libin Liu, Beijing (CN)

(73) Assignee: BOE TECHNOLOGY GROUP CO., LTD., Beijing (CN)

(21) Appl. No.: 16/642,447

(22) PCT Filed: Mar. 19, 2019
(86) PCT No.: PCT/CN2019/078645

§ 371 Date: Feb. 27, 2020

(30) Foreign Application Priority Data
May 21, 2018 (CN) 201810489559.3

(51) Int. Cl. G09G 3/3258; G09G 3/3233; H01L 27/32

(52) U.S. Cl. CPC G09G 3/3258; G09G 3/3233; H01L 27/3262; H01L 27/3276; H01L 27/1222; H01L 27/3272; G09G 2300/0426; G09G 2320/0233; H01L 27/3265

(57) ABSTRACT

A pixel circuit and a method of driving the same, a display panel and a method of forming the same and a display device are provided. The pixel circuit includes: a light-emitting element, a data writing sub-circuit, a storage sub-circuit and a driving transistor, where the driving transistor is a double-gate transistor. The data writing sub-circuit is configured to switch on or switch off a connection between the data line and the top gate of the driving transistor under a control of the gate line. The storage sub-circuit is configured to control a potential of the top gate of the driving transistor; the bottom gate of the driving transistor is connected to a first voltage input end; the first electrode of the driving transistor is connected to a power voltage input end, the second electrode of the driving transistor is connected to a first electrode of the light-emitting element; a second electrode of the light-emitting element is connected to a second voltage input end.

### CROSS-REFERENCE TO RELATED APPLICATION

This application claims a priority to Chinese Patent Application No. 201810489559.3 filed in China on May 21, 2018, the disclosure of which is incorporated herein in its entirety by reference.

### TECHNICAL FIELD

The present disclosure relates to the field of display technology, and in particular, to a pixel circuit and a method of driving the same, a display panel and a method of forming the same and a display device.

### BACKGROUND

The display panel in the related art may be a partially transparent display panel, that is, the display panel may be provided with a transparent display area and a normal display area (the normal display area is also a non-transparent display area).

In order to improve the transmittance of the transparent display area, the pixel circuit arranged in the transparent display area usually does not have a threshold compensation function.

In addition, since the data voltage ranges of the transparent display area and the normal display area are different, there may be a difference between the brightness of the transparent display area and the brightness of the normal display area (the brightness of the transparent display area is smaller), it is needed to perform a complex data compensation at the Integrated Circuit (IC) end to perform, which disadvantageously results in higher requirements for IC functions.

### SUMMARY

In a first aspect, a pixel circuit is provided in some embodiments of the present disclosure, including: a light-emitting element, a data writing sub-circuit, a storage sub-circuit and a driving transistor, where the driving transistor is a double-gate transistor, the double-gate transistor includes a top gate, a bottom gate, a first electrode and a second electrode; the data writing sub-circuit is connected to a gate line, a data line and the top gate of the driving transistor, and is configured to switch on or switch off a connection between the data line and the top gate of the driving transistor under a control of the gate line; the storage sub-circuit is connected to the top gate of the driving transistor, and is configured to control a potential of the top gate of the driving transistor; the bottom gate of the driving transistor is connected to a first voltage input end; the first electrode of the driving transistor is connected to a power voltage input end, the second electrode of the driving transistor is connected to a first electrode of the light-emitting element; the first voltage input end is configured to input a first voltage; a second electrode of the light-emitting element is connected to a second voltage input end; the second voltage input end is configured to input a second voltage.

In some embodiments of the present disclosure, the driving transistor is a P-type transistor, and the first voltage is a positive voltage.

In some embodiments of the present disclosure, the driving transistor is an N-type transistor, and the first voltage is a negative voltage.

In some embodiments of the present disclosure, the data writing sub-circuit includes a data writing transistor, a gate of the data writing transistor is connected to the gate line, a first electrode of the data writing transistor is connected to the data line, and a second electrode of the data writing transistor is connected to the top gate of the driving transistor.

In some embodiments of the present disclosure, the storage sub-circuit includes a storage capacitor; a first end of the storage capacitor is connected to the top gate of the driving transistor, a second end of the storage capacitor is connected to the second electrode of the driving transistor.

In some embodiments of the present disclosure, the pixel circuit further includes a light-emitting control sub-circuit;

the light-emitting control sub-circuit is connected to a light-emitting control end, the second electrode of the driving transistor and the first electrode of the light-emitting element, to switch on or switch off a connection between the second electrode of the driving transistor and the first electrode of the light-emitting element under a control of the light-emitting control end.

In some embodiments of the present disclosure, the light-emitting control sub-circuit includes a light-emitting control transistor, a gate of the light-emitting control transistor is connected to the light-emitting control end, a first electrode of the light-emitting control transistor is connected to the second electrode of the driving transistor, and a second electrode of the light-emitting control transistor is connected to the first electrode of the light-emitting element.

In some embodiments of the present disclosure, the light-emitting element is an organic light-emitting diode (OLED).

In some embodiments of the present disclosure, the data writing transistor and the light-emitting control transistor are both P-type transistors.

In some embodiments of the present disclosure, the double-gate transistor is a P-type transistor, and the first voltage is a constant positive voltage having a high voltage value.

In some embodiments of the present disclosure, the double-gate transistor is an N-type transistor, and the first voltage is a constant negative voltage having a low voltage value.

In some embodiments of the present disclosure, the pixel circuit is arranged in a transparent display area of a display panel.

In a second aspect, a method of driving a pixel circuit is provided in some embodiments of the present disclosure, applied to the pixel circuit in the first aspect, where the method includes: in each display period,

in a driving phase, inputting, by the first voltage input end, the first voltage to the bottom gate of the driving transistor; under a control of a first gate line, writing, by the data writing sub-circuit, into the top gate of the driving transistor a data voltage output by the data line, and controlling, by the storage sub-circuit, a potential of the top gate of the driving transistor, to turn on the driving transistor to drive the light-emitting element to emit light.

In some embodiments of the present disclosure, the pixel circuit further includes a light-emitting control sub-circuit, and the driving phase includes a data writing period and a light-emitting period in sequence, and the method of driving the pixel circuit includes: in the driving phase,

in the data writing period, inputting, by the first voltage input end, the first voltage to the bottom gate of the driving transistor; outputting, by the data line, the data voltage; under the control of the gate line, writing the data voltage into the top gate of the driving transistor by the data writing sub-circuit; maintaining, by the storage sub-circuit, the potential of the top gate of the driving transistor; and under a control of a light-emitting control line, switching off the connection between the second electrode of the driving transistor and the first electrode of the light-emitting element by the light-emitting control sub-circuit;

in the light-emitting period, inputting, by the first voltage input end, the first voltage to the bottom gate of the driving transistor; under the control of the gate line, switching off, by the data writing sub-circuit, the connection between the data line and the top gate of the driving transistor; under the control of the light-emitting control line, switching on, by the light-emitting control sub-circuit, the connection between the second electrode of the driving transistor and the first electrode of the light-emitting element; and controlling, by the storage sub-circuit, the potential of the top gate of the driving transistor, to turn on the driving transistor to drive the light-emitting element to emit light.

In a third aspect, a display panel is further provided in some embodiments of the present disclosure, including: a normal display area and a transparent display area, where the transparent display area of the display panel includes the pixel circuit in the first aspect.

In a fourth aspect, a method of forming a display panel is further provided in some embodiments of the present disclosure, applied to form the display panel in the third aspect, where the method includes:

forming, in the transparent display area of the display panel, the bottom gate, an active layer, the top gate, a source and a drain of the driving transistor in sequence, where the bottom gate is made of an opaque conductive material, and an orthographic projection of the active layer onto a plane of the bottom gate is within the bottom gate.

In a fifth aspect, a display device is further provided in some embodiments of the present disclosure, including the display panel in the third aspect.

### BRIEF DESCRIPTION OF THE DRAWINGS

In order to more clearly explain the technical solutions in the embodiments of the present disclosure or related technologies, the drawings used in the description of the embodiments are briefly described below. Obviously, the drawings in the following description are merely some embodiments of the present disclosure. For those skilled in the art, other drawings may be obtained based on these drawings without creative word.

FIG. 1 is a structural diagram of a pixel circuit in an embodiment of the present disclosure;

FIG. 2 is a structural diagram of a pixel circuit in another embodiment of the present disclosure;

FIG. 3 is a circuit diagram of a pixel circuit in an embodiment of the present disclosure;

FIG. 4 is an operation timing diagram of the pixel circuit shown in FIG. 3 in the present disclosure;

FIG. 5 is a schematic diagram of an area division of a display panel in an embodiment of the present disclosure;

FIG. 6 is a circuit diagram of a pixel circuit having a threshold compensation function arranged in the normal display area 52; and

FIG. 7 is a schematic structural diagram of a driving transistor included in a pixel circuit in a transparent display region of a display panel in an embodiment of the present disclosure.

### DETAILED DESCRIPTION

The technical solutions in the embodiments of the present disclosure will be clearly and completely described below with reference to the drawings in the embodiments of the present disclosure. Obviously, the described embodiments are only a part of the embodiments of the present disclosure, but not all of the implementations. Based on the embodiments in the present disclosure, all other embodiments obtained by a person ordinary skilled in the art without creative work shall fall within the scope of the present disclosure.

The transistors in all embodiments of the present disclosure may be thin film transistors or field effect transistors or other devices with the same characteristics. In the embodiment of the present disclosure, in order to distinguish the two electrodes of the transistor other than the gate, one of the electrodes is called a first electrode and the other electrode is called a second electrode. In actual operation, the first electrode may be a drain, and the second electrode may be a source; or, the first electrode may be a source, and the second electrode may be a drain.

The pixel circuit in the embodiment of the present disclosure includes a light-emitting element. The pixel circuit further includes a data writing sub-circuit, a storage sub-circuit and a driving transistor.

The driving transistor is a double gate transistor; the double gate transistor includes a top gate, a bottom gate, a first electrode and a second electrode.

The data writing sub-circuit is connected to a gate line, a data line, and a top gate of the driving transistor, and is configured to switch on or switch off a connection between the data line and the top gate of the driving transistor under a control of the gate line.

The storage sub-circuit is connected to the top gate of the driving transistor and is configured to control a potential of the top gate of the driving transistor.

The bottom gate of the driving transistor is connected to a first voltage input end, the first electrode of the driving transistor is connected to a power voltage input end, and the second electrode of the driving transistor is connected to a first electrode of the light-emitting element.

The second electrode of the light-emitting element is connected to a second voltage input end.

According to the pixel circuit in the embodiment of the present disclosure, the pixel circuit adopts a double gate transistor (the double gate transistor includes a top gate and a bottom gate) as a driving transistor, and controls the bottom gate to be connected to the first voltage input end to reduce the threshold voltage of the driving transistor, thereby increasing the driving current when the driving transistor is turned on, increasing the light-emitting brightness of the light-emitting element, and compensating the brightness difference between the transparent display area and the normal display area.

In a partially transparent display device, in order to improve the transmittance of the transparent display area, the pixel circuit arranged in the transparent display area does not have the threshold voltage compensation capability, resulting in the brightness of the normal display area (i.e., the opaque display area) is higher than that of the transparent display area. Therefore, the pixel circuit in the embodiment of the present disclosure is applied to the transparent display area, and a double gate transistor is used as a driving transistor to compensate for the brightness difference between the transparent display area and the normal display area.

In specific implementation, the first voltage input end is configured to input a first voltage to reduce a threshold voltage of the driving transistor, thereby increasing the turn-on degree of the driving transistor, and thereby increasing the driving current of the driving transistor. In addition, the voltage amplitude of the first voltage may be correspondingly set according to actual needs, and details thereof are not described herein again.

In some embodiments of the present disclosure, the driving transistor is a P-type transistor, and the first voltage is a positive voltage, so as to reduce a threshold voltage of the driving transistor.

In some embodiments of the present disclosure, the driving transistor is an N-type transistor, and the first voltage is a negative voltage, so as to reduce a threshold voltage of the driving transistor.

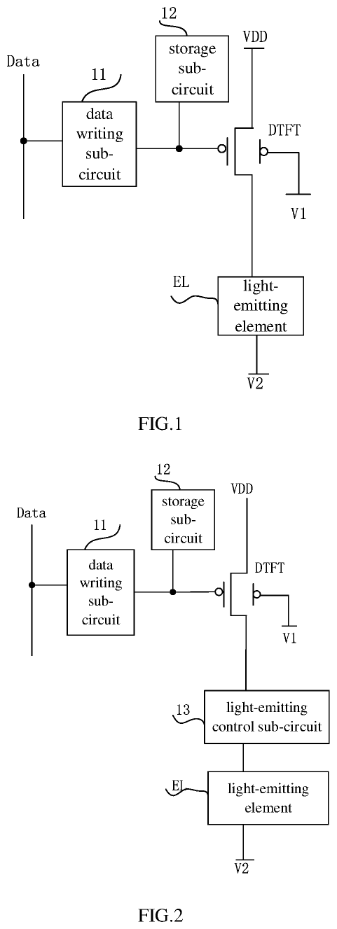

As shown in FIG. 1, a pixel circuit in an embodiment of the present disclosure includes a light-emitting element EL, and the pixel circuit further includes a data writing sub-circuit 11, a storage sub-circuit 12 and a driving transistor DTFT.

The driving transistor DTFT is a double gate transistor.

The data writing sub-circuit 11 is connected to a gate line Gate (not shown in FIG. 1), a data line Data and a top gate of the driving transistor DTFT, and is configured to switch on or switch off a connection between the data line Data and the top gate of the driving transistor DTFT under a control of the gate line Gate.

The storage sub-circuit 12 is connected to the top gate of the driving transistor DTFT and is configured to control the potential of the top gate of the driving transistor DTFT.

The bottom gate of the driving transistor DTFT is connected to a first voltage input end; a source of the driving transistor DTFT is connected to a power voltage input end, and a drain of the driving transistor is connected to a first electrode of the light-emitting element EL; the first voltage input end is configured to input a first voltage V1, and the power voltage input end is configured to input a power voltage VDD.

The second electrode of the light-emitting element EL is connected to a second voltage input end; the second voltage input end is configured to input a second voltage V2.

As described above, the pixel circuit shown in FIG. 1 in the embodiment of the present disclosure is applied to, for example, a transparent display area of a display panel.

In specific implementation, the light-emitting element EL may be an organic light-emitting diode, a first electrode of the light-emitting element EL may be an anode, a second electrode of the light-emitting element EL may be a cathode, and the second voltage V2 may be a low voltage, but not limited to this.

In the embodiment shown in FIG. 1, the DTFT is a P-type transistor. At this time, the first voltage V1 may be a constant positive voltage with a high voltage value, so as to reduce the threshold voltage of the driving transistor.

In actual operation, the DTFT may also be an N-type transistor. At this time, V1 may be a constant negative voltage with a low voltage value, so as to reduce the threshold voltage of the driving transistor.

The driving transistor included in the pixel circuit in the normal display area does not include a bottom gate. In the light-emitting period included in the driving phase, when the same voltage is input to the top gate of the driving transistor in the normal display area and the top gate of the driving transistor included in the pixel circuit in the transparent display area, the first voltage is applied to the bottom gate attached to the transparent display region, thereby increasing the conduction current of the driving transistor in the transparent region.

In embodiment of the present disclosure as shown in FIG. 1 a double-gate transistor is adopted (the double-gate transistor includes, for example, a top gate and a bottom gate) as a driving transistor DTFT. The bottom gate of the driving transistor DTFT is connected to a first voltage input end, thereby reducing the threshold voltage of the driving transistor DTFT, increasing the driving current when the driving transistor DTFT is turned on, increasing the light-emitting brightness of the light-emitting element EL, and compensating the brightness difference between the transparent display area and the normal display area.

Specifically, the data writing sub-circuit may include a data writing transistor, a gate thereof is connected to the gate line, a first electrode thereof is connected to the data line, and a second electrode thereof is connected to a top gate of the driving transistor.

Optionally, as shown in FIG. 2, the pixel circuit in the embodiment of the present disclosure may further include a light-emitting control sub-circuit 13;

The light-emitting control sub-circuit 13 is connected to a light-emitting control end EM, a drain of the driving transistor DTFT and a first electrode of the light-emitting element EL, and is configured to switch on or switch off a connection between the drain of the driving transistor DTFT and the first electrode of the light-emitting element EL under a control of the light-emitting control end EM.

The embodiment of the pixel circuit shown in FIG. 2 in the present disclosure is added with a light-emitting control sub-circuit 13, and during a data writing period included in the driving phase, the light-emitting control sub-circuit 13, under a control of the EM, switches off the connection between the drain of the DTFT and the first electrode of the EL; during the light-emitting period included in the driving phase, the light-emitting control sub-circuit 13, under a control of the EM, switches on the connection between the drain of the DTFT and the first electrode of the EL, so as to enable the DTFT to drive the EL to emit light.

In specific implementation, the light-emitting control sub-circuit 13 may include: a light-emitting control transistor, a gate thereof is connected to the light-emitting control end EM, a first electrode thereof is connected to a second electrode of the driving transistor DTFT, and a second electrode thereof is connected to the first electrode of the light-emitting element EL.

Specifically, the storage sub-circuit includes a storage capacitor.

A first end of the storage capacitor is connected to the top gate of the driving transistor, and a second end of the storage capacitor is connected to the second electrode of the driving transistor.

The pixel circuit described in the present disclosure is described below through a specific embodiment.

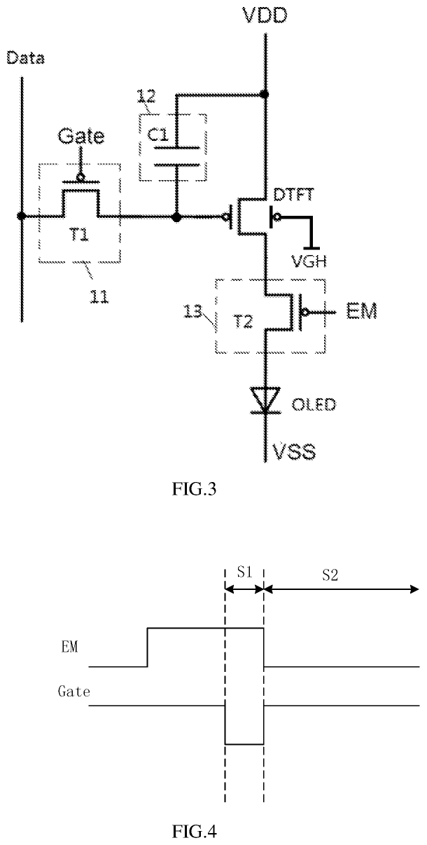

As shown in FIG. 3, the pixel circuit in some embodiments of the present disclosure includes a light-emitting element, a data writing sub-circuit 11, a storage sub-circuit 12, a light-emitting control sub-circuit 13 and a driving transistor DTFT.

The light-emitting element is an organic light-emitting diode OLED.

The driving transistor DTFT is a double gate transistor.

The bottom gate of the driving transistor DTFT is connected to a high-voltage input end; the source of the driving transistor DTFT is connected to a power voltage input end; the high-voltage input end is configured to input a high voltage VGH, and the power voltage input end is configured to input a power voltage VDD.

A cathode of the organic light-emitting diode OLED is connected to a low-voltage input end; the low-voltage input end is configured to input a low voltage VSS.

The data writing sub-circuit 11 includes a data writing transistor T1, a gate thereof is connected to the gate line Gate, a source thereof is connected to the data line Data, and a drain thereof is connected to the top gate of the driving transistor DTFT.

The storage sub-circuit 12 includes: a storage capacitor C1; a first end of the storage capacitor C1 is connected to the top gate of the driving transistor DTFT, and a second end of the storage capacitor C1 is connected to the drain of the driving transistor DTFT.

The light-emitting control sub-circuit 13 includes a light-emitting control transistor T2.

The gate of T2 is connected to the light-emitting control end EM, the source of T2 is connected to the drain of the driving transistor DTFT, and the drain of T2 is connected to the anode of the organic light-emitting diode OLED.

In the specific embodiment shown in FIG. 3, T1 and T2 are both P-type transistors, but not limited thereto.

In the specific embodiment of the pixel circuit shown in FIG. 3, the DTFT is a P-type transistor, but is not limited thereto.

In the specific embodiment of the pixel circuit shown in FIG. 3, the bottom gate of the DTFT is connected to a high voltage VGH, so as to reduce the threshold voltage of the DTFT.

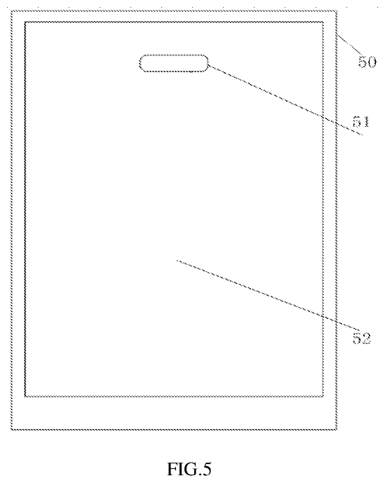

When the pixel circuit shown in FIG. 3 of embodiment of the present disclosure is in operation, as shown in FIG. 4, the driving period includes a data writing period S1 and a light-emitting period S2 in sequence.

During the data writing period S1, EM outputs a high level, Gate outputs a low level, the bottom gate of the DTFT is connected to VGH, the data outputs the data voltage Vdata, and T1 is turned on to write Vdata to the top gate of the DTFT, C1 maintains the potential of the top gate of the DTFT, and T2 is turned off to switch off the connection between the drain of the DTFT and the anode of the OLED.

In the light-emitting stage S2, EM outputs a low level, Gate outputs a high level, the bottom gate of the DTFT is connected to VGH, T1 is turned off, and C1 controls the potential of the top gate of the DTFT to control the DTFT to be turned on and T2 to be turned on, so as to switch on the connection between the drain of the DTFT and the anode of the OLED, the DTFT drives the OLED to emit light; in the specific embodiment of the pixel circuit shown in FIG. 3, the DTFT is a double gate transistor, and the bottom gate of the DTFT is connected to the high voltage VGH, so as to reduce the threshold voltage of the DTFT, thereby increasing the turn-on amplitude of the DTFT, increasing the driving current of the DTFT in the light-emitting stage, and thereby improving the light-emitting brightness of the OLED.

The method of driving the pixel circuit in the embodiment of the present disclosure is applied to the above-mentioned pixel circuit. The method of driving the pixel circuit includes: in each display period,

in a driving phase, inputting, by the first voltage input end, the first voltage to the bottom gate of the driving transistor; under a control of a first gate line, writing, by the data writing sub-circuit, into the top gate of the driving transistor a data voltage output by the data line, and controlling, by the storage sub-circuit, a potential of the top gate of the driving transistor, to turn on the driving transistor to drive the light-emitting element to emit light.

According to the method of driving the pixel circuit in the embodiment of the present disclosure, a double gate transistor (the double gate transistor includes, for example, a top gate and a bottom gate) is adopted as a driving transistor, and controls the bottom gate to be connected to a first voltage input end, so as to reducing the threshold voltage of the driving transistor, and thereby increasing the driving current of the driving transistor when the driving transistor is turned on, increasing the light-emitting brightness of the light-emitting element, and compensating the brightness difference between the transparent display area and the normal display area.

Specifically, the pixel circuit further includes a light-emitting control sub-circuit, the driving phase includes a data writing period and a light-emitting period in sequence, and the method of driving the pixel circuit includes: in the driving phase,

in the data writing period, inputting, by the first voltage input end, the first voltage to the bottom gate of the driving transistor; outputting, by the data line, the data voltage; under the control of the gate line, writing the data voltage into the top gate of the driving transistor by the data writing sub-circuit; maintaining, by the storage sub-circuit, the potential of the top gate of the driving transistor; and under a control of a light-emitting control line, controlling, switching off the connection between the second electrode of the driving transistor and the first electrode of the light-emitting element by the light-emitting control sub-circuit;

in the light-emitting period, inputting, by the first voltage input end, the first voltage to the bottom gate of the driving transistor; under the control of the gate line, switching off, by the data writing sub-circuit, the connection between the data line and the top gate of the driving transistor; under the control of the light-emitting control line, switching on, by the light-emitting control sub-circuit, the connection between the second electrode of the driving transistor and the first electrode of the light-emitting element; and controlling, by the storage sub-circuit, the potential of the top gate of the driving transistor, to turn on the driving transistor to drive the light-emitting element to emit light.

The display panel in the embodiment of the present disclosure includes a transparent display area and a normal display area, and the transparent display area of the display panel is, for example, provided with the pixel circuit described above.

In specific implementation, as shown in FIG. 5, the display panel 50 in the embodiment of the present disclosure may include a transparent display area 51 and a normal display area 52, where the normal display area 52 is a non-transparent display area.

The pixel circuit in the embodiment of the present disclosure is arranged in the transparent display area 51, and the normal display area 52, for example, is provided with a pixel circuit having a threshold compensation function in the related art. Of course, the embodiments of the present disclosure are not limited thereto.

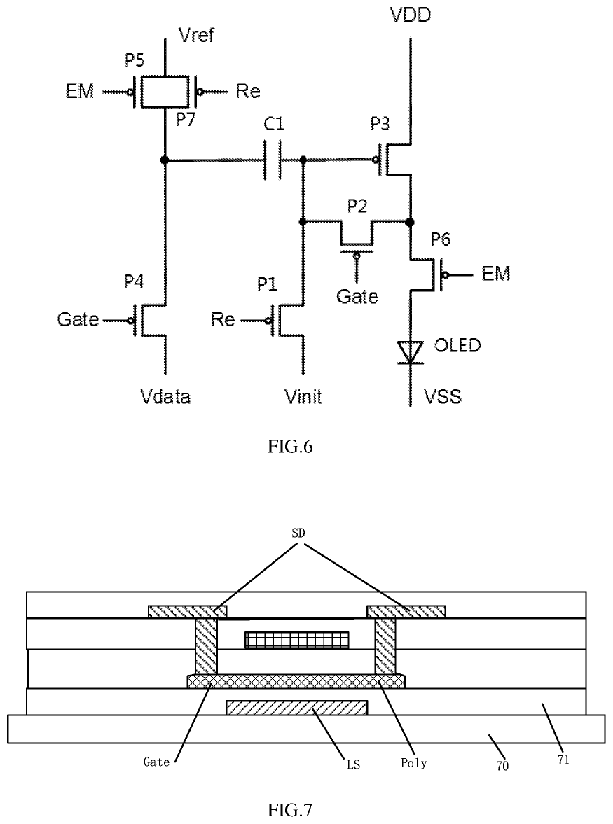

For example, as shown in FIG. 6, a pixel circuit having a threshold compensation function arranged in the normal display area 52 may include a first transistor P1, a second transistor P2, a third transistor P3 (in FIG. 6, P3 is a driving transistor), the fourth transistor P4, the fifth transistor P5, the sixth transistor P6, the seventh transistor P7, the storage capacitor C1 and the organic light-emitting diode OLED. EM is a light-emitting control end, Vref is a reference voltage, VDD is a power voltage, VSS is a low voltage, Vinit is an initial voltage, Vdata is a data voltage, and Re is a reset control end.

Comparing FIG. 6 with FIG. 3, it can be seen that the pixel circuit shown in FIG. 6 arranged in the normal display area 52 has a large number of transistors and has a threshold compensation function. When the pixel circuit shown in FIG. 6 works, the current Ioled flowing through the OLED during the light-emitting stage is K (Vdata-VDD-Vth) 2, where K is a current coefficient of P3 and Vth is a threshold voltage of P3. In order to ensure the transmittance in the transparent display area 51 in the display panel described in the embodiment of the present disclosure, the pixel circuit arranged in the transparent display area 51 cannot be provided with a transistor for threshold voltage compensation. The driving transistor included in the pixel circuit arranged in the transparent display region 51 is set as a double-gate transistor, and the bottom gate of the driving transistor is controlled to be connected to a first voltage to reduce the threshold voltage of the driving transistor, thereby improving the light-emitting brightness of the light-emitting element, and compensating the brightness difference between the transparent display area 51 and the normal display area 52.

The method of manufacturing a display panel in the embodiment of the present disclosure is applied to form the above display panel. The method of forming the display panel includes:

forming, in the transparent display area of the display panel, the bottom gate, an active layer, the top gate, a source and a drain of the driving transistor in sequence, where the bottom gate is made of an opaque conductive material, and an orthographic projection of the active layer onto a plane of the bottom gate is within the bottom gate.

FIG. 7 illustrates a driving transistor included in a pixel circuit arranged in a transparent display area.

As shown in FIG. 7, the mark 70 represents a display substrate, the mark LS represents a light shielding layer, the mark Poly represents an active layer, the mark Gate represents a gate metal layer, and the mark SD represents a source/drain metal layer. The reference numeral 71 is an insulating layer. The light shielding layer LS serves as a bottom gate, and the gate metal layer Gate serves as a top gate. The light shielding layer LS is made of an opaque conductive material, and the light shielding layer LS may protect the channel of transistor in the transparent display area from being affected by the underlying devices.

In actual operation, the light shielding layer LS is controlled by an independent voltage.

The display device in the embodiment of the present disclosure includes the display panel described above.

The display device in the embodiments of the present disclosure may be any product or component having a display function, such as a mobile phone, a tablet computer, a television, a display, a notebook computer, a digital photo frame, a navigator, and the like.

The above are merely embodiments of the present disclosure, it should be appreciated that those of ordinary skill in the art may make further modifications and improvements without departing from the principle of the present disclosure, and these modifications and improvements shall also fall within the scope of the present disclosure.

1. A pixel circuit, comprising: a light-emitting element, a data writing sub-circuit, a storage sub-circuit and a driving transistor, wherein
the driving transistor is a double-gate transistor, the double-gate transistor comprises a top gate, a bottom gate, a first electrode and a second electrode;
the data writing sub-circuit is connected to a gate line, a data line and the top gate of the driving transistor, and is configured to switch on or switch off a connection between the data line and the top gate of the driving transistor under a control of the gate line;
the storage sub-circuit is connected to the top gate of the driving transistor, and is configured to control a potential of the top gate of the driving transistor;
the bottom gate of the driving transistor is connected to a first voltage input end; the first electrode of the driving transistor is connected to a power voltage input end, the second electrode of the driving transistor is connected to a first electrode of the light-emitting element; the first voltage input end is configured to input a first voltage;
a second electrode of the light-emitting element is connected to a second voltage input end; the second voltage input end is configured to input a second voltage.

2. The pixel circuit according to claim 1, wherein the driving transistor is a P-type transistor, and the first voltage is a positive voltage.

3. The pixel circuit according to claim 1, wherein the driving transistor is an N-type transistor, and the first voltage is a negative voltage.

4. The pixel circuit according to claim 1, wherein the data writing sub-circuit comprises a data writing transistor, a gate of the data writing transistor is connected to the gate line, a first electrode of the data writing transistor is connected to the data line, and a second electrode of the data writing transistor is connected to the top gate of the driving transistor.

5. The pixel circuit according to claim 1, wherein the storage sub-circuit comprises a storage capacitor; a first end of the storage capacitor is connected to the top gate of the driving transistor, a second end of the storage capacitor is connected to the second electrode of the driving transistor.

6. The pixel circuit according to claim 1, wherein the pixel circuit further comprises a light-emitting control sub-circuit;
the light-emitting control sub-circuit is connected to a light-emitting control end, the second electrode of the driving transistor and the first electrode of the light-emitting element, and is configured to switch on or switch off a connection between the second electrode of the driving transistor and the first electrode of the light-emitting element under a control of the light-emitting control end.

7. The pixel circuit according to claim 6, wherein the light-emitting control sub-circuit comprises a light-emitting control transistor, a gate of the light-emitting control transistor is connected to the light-emitting control end, a first electrode of the light-emitting control transistor is connected to the second electrode of the driving transistor, and a second electrode of the light-emitting control transistor is connected to the first electrode of the light-emitting element.

8. The pixel circuit according to claim 1, wherein the light-emitting element is an organic light-emitting diode (OLED).

9. The pixel circuit according to claim 7, wherein the data writing transistor and the light-emitting control transistor are both P-type transistors.

10. The pixel circuit according to claim 1, wherein the double-gate transistor is a P-type transistor, and the first voltage is a constant positive voltage having a high voltage value.

11. The pixel circuit according to claim 1, wherein the double-gate transistor is an N-type transistor, and the first voltage is a constant negative voltage having a low voltage value.

12. The pixel circuit according to claim 1, wherein the pixel circuit is arranged in a transparent display area of a display panel.

13. A method of driving a pixel circuit, applied to the pixel circuit according to claim 1, wherein the method comprises: in each display period,
in a driving phase,
inputting, by the first voltage input end, the first voltage to the bottom gate of the driving transistor;
under a control of a first gate line, writing, by the data writing sub-circuit, into the top gate of the driving transistor a data voltage output by the data line, and controlling, by the storage sub-circuit, a potential of the top gate of the driving transistor, to turn on the driving transistor to drive the light-emitting element to emit light.

14. The method of driving a pixel circuit according to claim 13, wherein the pixel circuit further comprises a light-emitting control sub-circuit, and the driving phase comprises a data writing period and a light-emitting period in sequence, and the method of driving the pixel circuit comprises: in the driving phase,
in the data writing period,
inputting, by the first voltage input end, the first voltage to the bottom gate of the driving transistor,
outputting, by the data line, the data voltage,
under the control of the gate line, writing, by the data writing sub-circuit, the data voltage into the top gate of the driving transistor,
maintaining, by the storage sub-circuit, the potential of the top gate of the driving transistor, and
under a control of a light-emitting control line, switching off the connection between the second electrode of the driving transistor and the first electrode of the light-emitting element by the light-emitting control sub-circuit;
in the light-emitting period,
inputting, by the first voltage input end, the first voltage to the bottom gate of the driving transistor,
under the control of the gate line, switching off, by the data writing sub-circuit, the connection between the data line and the top gate of the driving transistor,
under the control of the light-emitting control line, switching on, by the light-emitting control sub-circuit, the connection between the second electrode of the driving transistor and the first electrode of the light-emitting element, and
controlling, by the storage sub-circuit, the potential of the top gate of the driving transistor, to turn on the driving transistor to drive the light-emitting element to emit light.

15. A display panel, comprising: a normal display area and a transparent display area, wherein the transparent display area of the display panel comprises the pixel circuit according to claim 1.

16. A method of forming a display panel, applied to form the display panel according to claim 15, wherein the method comprises:
forming, in the transparent display area of the display panel, the bottom gate, an active layer, the top gate, a source and a drain of the driving transistor in sequence, wherein the bottom gate is made of an opaque conductive material, and an orthographic projection of the active layer onto a plane of the bottom gate is within the bottom gate.

17. A display device comprising the display panel according to claim 15.
